(19) United States
(12) Patent Application Publication
(10) Pub. No.: US 2012/0285512 A1
(43) Pub. Date: Nov. 15, 2012

(54) SOLAR CELL ARRAY AND THIN-FILM SOLAR MODULE AND PRODUCTION METHOD THEREFOR

(76) Inventors: Jan Boris Philipp, Munich (DE); Thomas Happ, Munich (DE)

(21) Appl. No.: 13/519,578

(22) PCT Filed: Jan. 27, 2011
(86) PCT No.: PCT/EP2011/051133

§ 371 Date: Aug. 3, 2012

(30) Foreign Application Priority Data
Jan. 29, 2010 (EP) 10152086.4

(51) Int. Cl. H01L 31/05; H01L 31/18

(52) U.S. Cl. 136/249; 438/80; 257/E31.124

(57) ABSTRACT

A solar cell array is described which can be designed in particular as a thin-film solar module. A production method for a solar cell array is further described.

The invention relates to a solar cell array with integrated, serially connected solar cells, in particular for use for thin-film solar modules, as well as a method for their production.

Solar modules for the photovoltaic conversion of sunlight into electric power are increasingly used for energy generation. In terms of efficiency, thin-film solar modules based on polycrystalline chalcopyrite semiconductors have proven advantageous with, in particular, copper-indium diselenide (CuInSe₂ or CIS) distinguished by a particularly high absorption coefficient because of its band gap suited to the spectrum of sunlight. Since with individual solar cells only voltage levels of less than 1 V can be reached, a plurality of solar cells are serially connected in a solar module in order to thus obtain a technically useful output voltage. For this, thin-film solar modules offer the particular advantage that the solar cells can already be connected serially in an integrated form during production of the films. Such an integrated series connection of individual solar cells has already been described several times in the patent literature. Reference is made merely by way of example to patent DE 4324318 C1.

Usually, a connection of the thin-film solar module to an electrical load occurs by means of a connection box that serves, mounted on the back side of the solar module and, for example, having a contact terminal, for the connecting contacts of the thin-film solar module, which contacts are typically configured as metal strips. However, to reduce electrical wiring within the thin-film solar module, thin-film solar modules with two connection boxes are also known.

In contrast, the object of the present invention consists in advantageously improving conventional thin-film solar modules with integrated solar cells, with, in particular, improvement of the long-term stability and durability of the module and reduction of its production costs. This and further objects are accomplished according to the proposal of the invention by means of a solar cell array or by means of a thin-film solar module incorporating such a solar cell array, as well as by means of the method for its production with the characteristics of the coordinated claims. Advantageous embodiments of the invention are indicated by means of the characteristics of the subclaims.

According to one aspect of the invention, a solar cell array with integrated, series-connected solar cells is presented.

The solar cell array according to the invention comprises a substrate, onto which a layer structure having a plurality of layers is applied, which layer structure comprises a first electrode layer, a second electrode layer, and a semiconductor layer disposed between the two electrode layers. It is understood that this list is in no way complete, but, rather, that the layer structure can include further layers. Each layer can comprise one or a plurality of individual layers. A pn-junction, i.e., a sequence of layers with a different conductor type, is formed by the layer structure. In particular embodiments, the pn-junction is formed by a hetero-junction.

In the solar cell array according to the invention, the layer structure is divided into a plurality of regions that are electrically separated from each other by one or a plurality of region trenches. In each of these regions, a solar cell string is configured that consists of one or a plurality of series-connected, rectified solar cells. Each solar cell has a first and second electrode that are formed in the first and second electrode layer, as well as a semiconductor material located between the two electrodes that is formed by the semiconductor layer. It can be advantageous for adjacent or directly contiguous solar cell strings to have an antiparallel forward direction.

The solar cell array according to the invention further comprises a first connecting contact and a second connecting contact that are electrically connected to each other by the solar cell strings. For this purpose, the solar cell strings are series connected by one or a plurality of intermediate contacts.

Moreover, the solar cell array according to the invention includes at least one connection housing (e.g., connection box) in which the two connecting contacts are electrically connected. For this purpose, the connection housing is provided with at least one device suitable for this, for example, a terminal device. The connection housing can serve for the connection of the solar cell array to a further electrical device.

In an advantageous embodiment of the solar cell array according to the invention that is particularly simple to implement from a technical standpoint, the layer structure is divided into two regions that are electrically separated from each other by a single region trench, in which, in each case, a solar cell string is configured. Advantageously, the two solar cell strings have an antiparallel forward direction. The first connecting contact and the second connecting contact are electrically connected to each other by the two solar cell strings, with the two solar cell strings series connected by a single intermediate contact. In addition, the two connecting contacts are electrically connected in a common connection housing.

In a further advantageous embodiment of the solar cell array according to the invention that is particularly simple to implement from a technical standpoint, the layer structure is divided into four regions that are electrically separated from each other by three region trenches in which, in each case, a solar cell string is configured. Advantageously, contiguous solar cell strings have an antiparallel forward direction. In this case, the first connecting contact and the second connecting contact are electrically connected to each other by the four solar cell strings, with the four solar cell strings series connected by three intermediate contacts. In addition, the two connecting contacts are connected, in each case, to a separate connection housing.

In the solar cell array according to the invention, in particular in the above embodiments, costs can advantageously be saved in production by using a smaller number of connection housings in comparison to conventional solar cell arrays. In addition, the long-term stability and durability of the solar cell array can be improved by this. Further advantages of the invention emerge from the description of the figures.

In a further advantageous embodiment of the solar cell array according to the invention, the various regions of the layer structure, in each of which a solar cell string is configured, are arranged next to each other in a row, with the two connecting contacts arranged opposite at least one Intermediate contact. It can be particularly advantageous for the solar cells to be configured in each case as a strip with the solar cell strings electrically connected to each other by an intermediate contact having an at least roughly U-shaped configuration. It can also be advantageous for the connection contacts and intermediate contacts to be configured in each case in the form of a contact strip. By means of these measures, the solar cell array according to the invention can be implemented in a particularly simple manner from a technical standpoint.

According to a further aspect of the invention, a thin-film solar module with integrated, series-connected solar cells is presented that has a solar cell array as described above, in which each solar cell is configured in the form of a solar cell suitable for the photovoltaic conversion of sunlight into electrical power.

In an advantageous embodiment of the solar module according to the invention, the thin-film solar cells are deposited on a carrier substrate. The carrier substrate can be turned facing the incidence of light, also referred to as a superstrate configuration, or turned away from the incidence of light, also referred to as a substrate configuration. In the substrate configuration, the first electrode layer is configured in the form of a transparent front electrode layer and the second electrode layer as a rear electrode layer, wherein the semiconductor layer is disposed on a side of the rear electrode layer facing the front electrode layer. In the substrate configuration, shadowing of photovoltaically active regions can be avoided in a particularly advantageous manner through electrical connection of the two connecting contacts, for example, to a common connection housing. Nevertheless, it would, however, also be conceivable to provide the superstrate configuration for the thin-film solar module according to the invention in which the incidence of light occurs through a transparent carrier substrate.

In a further advantageous embodiment of the thin-film solar module according to the invention, the semiconductor layer includes a chalcopyrite compound, which can, in particular, be a I-III-VI-semiconductor from the group copper-indium/gallium-disulfide/diselenide (Cu(InGa)(SSe)₂), for example, copper-indium-diselenide (CuInSe₂ or CIS) or related compounds. These include one or a plurality of the elements Cu, In, Ga, Al, Zn, Sn, S, Se, or Te. If the semiconductor layer is chalcopyrite based, the substrate configuration is particularly advantageous. However, the semiconductor layer can also include, according to the invention, cadmium telluride, amorphous, micromorphous, microcrystalline, and/or polycrystalline thin-film silicon.

According to a further aspect of the invention, a method for the structuring of a layer structure of a thin-film solar module comprising a first electrode layer, a second electrode layer, and a semiconductor layer disposed between the two electrode layers is presented, comprising the following steps:
Creation of a first structuring line in the second electrode layer, by means of which the second electrode layer is divided into second layer sections electrically separated from each other,
Creation of a second structuring line in the layer structure for the electrical connection of the first electrode layer and the second electrode layer for series connection of the solar cells,
Creation of a third structuring line in the first electrode layer, by means of which the first electrode layer is divided into first layer sections electrically separated from each other, wherein a structuring line, selected from among the first through the third structuring lines is guided such that it has a linear progression over at least two regions electrically separated from each other, while the two remaining structuring lines and this structuring line are offset relative to each other such that a sequence of the structuring lines is reversed.

According to a further aspect of the invention, a method for production of a thin-film solar module is presented, comprising the following steps:
Application of a layer structure on a substrate, wherein the layer structure has at least a first electrode layer, a second electrode layer, and a semiconductor layer disposed between the two electrode layers, by means of which a pn-junction is formed,
Structuring of the layer structure by a method as described above for the structuring of the layer structure of a thin-film solar module, wherein a plurality of solar cell strings is created, each of which consists of one or a plurality of series-connected, rectified solar cells, wherein solar cell strings adjacent each other preferably have an antiparallel forward direction,
Introduction of one or a plurality of region trenches in the layer structure, such that different module regions, each of which contains a separate solar cell string, are electrically separated from each other,
Series connection of the solar cell strings by formation of one or a plurality of intermediate contacts,
Formation of a first connecting contact and a second connecting contact that are electrically conductively connected to the solar cell strings,
Connection of the two connecting contacts in at least one connection housing.

In an advantageous embodiment of the method according to the invention, the two connecting contacts are connected in a connection housing such that it is possible to forgo expensive wiring for the electrical connection of the two connecting contacts with the common connection box.

### BRIEF DESCRIPTION OF THE DRAWINGS

The invention is now explained in detail with reference to exemplary embodiments, referring to the accompanying figures. They depict:

FIG. 1 a schematic representation of a first exemplary embodiment of the thin-film solar module according to the invention in plan view;

FIG. 2 schematic cross-sectional representations of the thin-film solar module of FIG. 1 in the intermediate region (left image) and edge region (right image);

FIG. 3 schematic representations to illustrate the structuring of the layer structure of the thin-film solar module according to the invention of FIG. 1;

FIG. 4A-4B schematic representations of structure lines to illustrate the structuring of the layer structure of the thin-film solar module according to the invention of FIG. 1;

FIG. 5A-5B different schematic representations of structure lines to illustrate variants to the structuring of the layer structure of the thin-film solar module according to the invention of FIG. 1;

FIG. 6 a schematic perspective representation of a second exemplary embodiment of the thin-film solar module according to the invention.

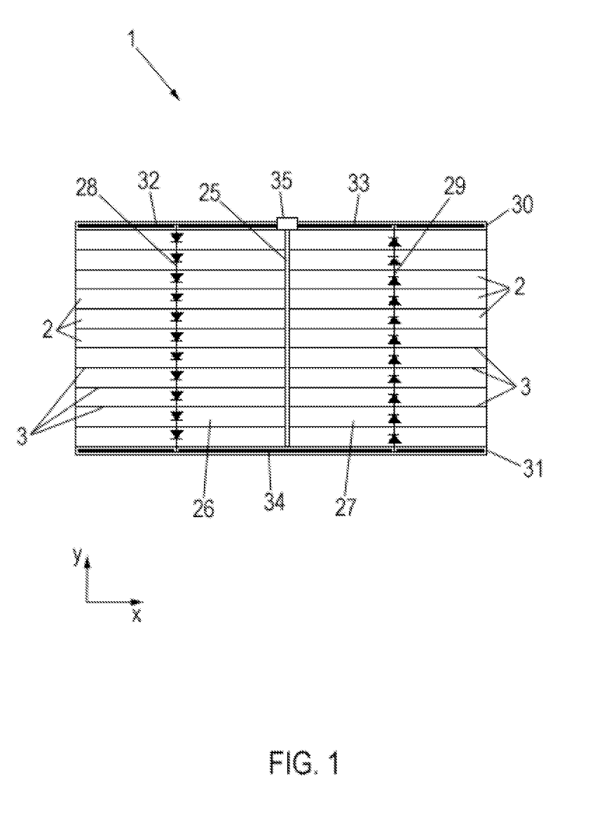

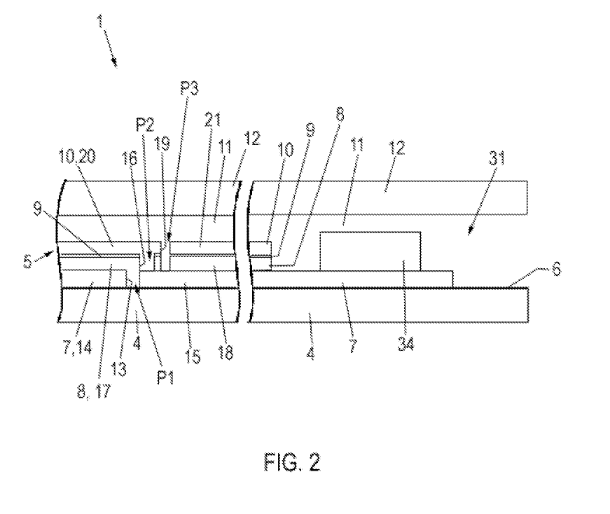

Reference is first made to FIG. 1 and FIG. 2, in which, using a schematic top view and various cross-sectional details, a thin-film solar module, referenced as a whole by the reference character 1, is illustrated. The thin-film solar module 1 serving for the photovoltaic conversion of sunlight into electrical energy represents an embodiment of the solar cell array according to the invention. Here, the thin-film solar module 1 comprises a plurality of series-connected, integrated solar cells 2 that represent an embodiment of the solar cells of the solar cell array according to the invention.

The thin-film solar module 1 has a structure corresponding to the substrate configuration, i.e., it has an electrically insulating substrate 4 with a layer structure 5 made of thin layers applied thereon, wherein the layer structure 5 is disposed on a main light-incident-side surface 6 of the substrate 4. The substrate 4 is made here, for example, of glass with a relatively low light transmittance, with it equally possible to use other insulating materials with sufficient strength as well as inert behavior relative to the process steps performed.

The layer structure 5 comprises a rear electrode layer 7 disposed on the main surface 6 of the substrate 4, which is made, for example, from an opaque metal such as molybdenum (Mo) and can be applied, for example, by cathode sputtering, on the substrate 4. The rear electrode layer 7 has, for example, a layer thickness of approx. 1 μm. In another embodiment, the rear electrode layer can also be made of a layer stack of different individual layers. A photovoltaically active absorber layer 8 made of a doped semiconductor whose band gap is preferably capable of absorbing the greatest possible share of the sunlight is deposited on the rear electrode layer 7. The absorber layer 8 is made, for example, of a p-conducting chalcopyrite semiconductor, for example, of a compound of the group Cu(InGa)(SSe)₂, in particular sodium (Na)-doped copper-indium-diselenide (CuInSe₂). The absorber layer 8 has, for example, a layer thickness in the range of 1-5 μm and is, for example, approx. 2 μm. A buffer layer 9 (not shown in detail in the figures), which consists here of a single layer of cadmium sulfide (CdS) and a single layer of intrinsic zinc oxide (i-ZnO), is deposited on the absorber layer 8. The buffer layer 9 has, for example, a smaller layer thickness than the absorber layer 8. A front electrode layer 10 is applied, for example, by vapor deposition, on this buffer layer 9. The front electrode layer 10 (“window layer”) is transparent to radiation in the spectral range susceptible to the absorber layer 8, to ensure only a slight weakening of the incident sunlight. The transparent front electrode layer 10, which can, by way of generalization, be referred to as a TCO-layer (TCO=transparent conductive [oxide] electrode), is based on a doped metal oxide, for example, n-conductive, aluminum (Al)-doped zinc oxide (AZO). Via the front electrode layer 10, together with the buffer layer 9 and the absorber layer 8, a pn-hetero-junction (i.e., a sequence of different layers of the opposing conductor type) is formed. The layer thickness of the front electrode layer 10 is, for example, approx. 800 nm

For protection against environmental influences, a plastic layer 11, made, for example, of polyvinyl butyral (PVB) or ethylene vinyl acetate (EVA), is applied on the front electrode layer 10. In addition, the layer structure 5 is sealed with a cover plate 12 transparent to sunlight, which is, for example, made of extra white glass having a low content of iron.

To increase the total module voltage, the module surface of the thin-film solar module 1 is divided into a plurality of individual solar cells 2 that are connected to each other in a first solar cell string 28 and a second solar cell string 29, series connected in each case. For this purpose, the layer structure 5 is structured with the use of a suitable structuring technology such as laser writing and mechanical processing, for example, by means of drossing or scratching. It is important here that the loss of photoactive surface be as limited as possible and that the structuring technology used is selective for the material to be removed. Such structuring typically comprises three structuring steps for each solar cell 3, abbreviated with the acronyms P1, P2, P3. This is further explained in detail with reference to FIG. 2, left image.

In a first structuring step P1, the rear electrode layer 7 is interrupted by creation of a first layer trench 13, producing a first rear electrode section 14 and a second rear electrode section 15 insulated against it. The first layer trench 13 is formed, in this case, preferably by laser writing, for example, by means of an excimer laser or Neodym-YAG-laser, or by mechanical processing of the rear electrode layer 7. The first layer trench 13 is formed before the application of the absorber layer 8 and is filled in at the time of application of the absorber layer 8 by the semiconductor material of this layer.

In a second structuring step P2, the two semiconductive layers, i.e., the absorber layer 8 and the buffer layer 9 are interrupted by the creation of a second layer trench 16, producing a first semiconductor section 17 and a second semiconductor section 18 insulated against it. The second layer trench 16 is formed, in this case, preferably by laser writing, for example, by means of an excimer laser or Neodym-YAG-laser. The second layer trench 16 is formed before the application of the front electrode layer 10 and is filled in at the time of application of the front electrode layer 10 by the electrically conductive material of this layer.

In a third structuring step P3, the front electrode layer 10, the buffer layer 9, and the absorber layer 8 are interrupted by the creation of a third layer trench 19, producing, in addition to the interrupted sections of the semiconductive layers, a first front electrode section 20 and a second front electrode section 21 insulated against it. The third layer trench 19 is formed, in this case, by mechanical processing. The third layer trench 19 is formed before the application of the plastic layer 11 and is filled in at the time of application of the plastic layer 11 by the insulating material of this layer. Alternatively, it would be conceivable for the third layer trench 19 to interrupt only the front electrode layer 10.

Thus, by means of the three structuring steps P1, P2, P3, two series-connected solar cells 2 are formed, with the first front electrode section 20 and the first rear electrode section 14 forming a front or rear electrode of the one solar cell 2 and the second front electrode section 21 and the second rear electrode section 15 forming a front or rear electrode of the other solar cell 2. In this process, the front electrode of the one solar cell 2 is electrically conductively connected to the rear electrode of the other solar cell 2.

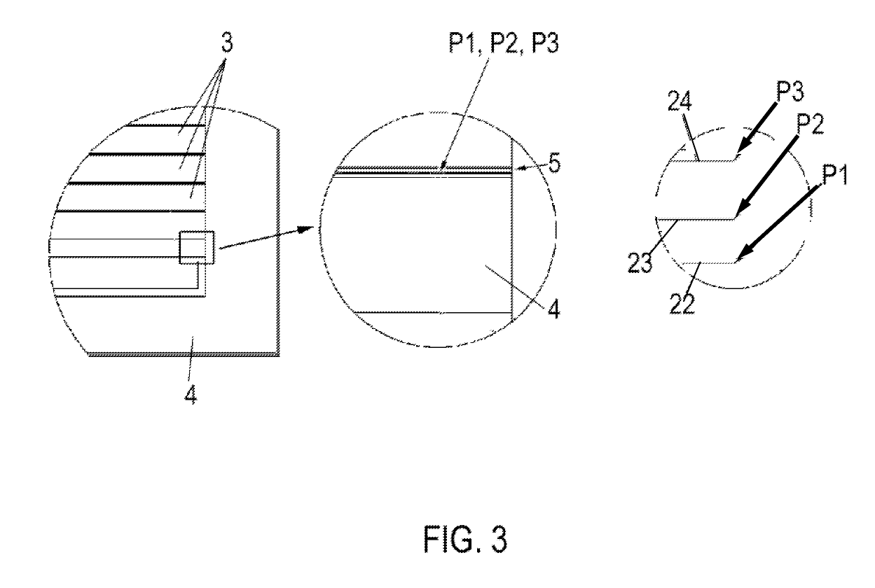

In the structuring steps P1, P2, P3, the layer trenches 13, 16, 19 are formed along structuring lines that are referred to according to the designation of the structuring steps P1, P2, P3 as first, second, and third structuring lines 22-24. In FIG. 3, the three structuring lines 22-24 are depicted schematically, with the left image showing a top view of a detail of the thin-film solar module 1, the center image showing a detailed view through the thin-film solar module 1 corresponding to the zone identified, and the right image showing a top view of an individual solar cell 2 to illustrate structuring lines 22-24.

As is discerned from FIG. 1, the thin-film solar module 1 has a rectangular shape in the top view, wherein the correspondingly rectangular layer structure 5 is divided by a central region trench 25, in which the layer structure 5 is completely removed all the way to the substrate 4, into a first module region 26 and a second module region 27 electrically separated from the first module region. The two module regions 26, 27 have the same shape and size and are arranged next to each other in a first direction (x) defined by the longer dimension of the thin-film solar module 1 or substrate 4. The first direction together with a second direction (y) perpendicular thereto spans a plane that is parallel to the main surface 6 of substrate 4. The region trench 25 discernibly extends in a straight line along the second direction (y).

The two module regions 26, 27 have, respectively, a separate solar cell string, with the first solar cell string 28 formed in the first module region 26 and the second solar cell string 29 in the second module region 27. In the two solar cell strings 28, 29, the solar cells 2 are, in each case, rectified and series connected, with each solar cell 2 identified by a solar cell symbol and the solar cell strings 28, 29 identified by the linked solar cell symbols. In FIG. 1, each solar cell string 28, 29 includes, for example, eleven solar cells 2, whereas it is understood that each of these can include a larger or smaller number of solar cells 2. Each solar cell string 28, 29 can have, for example, from 40 to 150, preferably from 50 to 110, particularly preferably from 100 to 110, and very particularly preferably 104 series-connected, rectified solar cells 2.

The strip-shaped solar cells 2 extend along the first direction (x) and are disposed along the second direction (y), with adjacent solar cells 2 separated from each other along the first direction (x) by a running (theoretical) separating line 3 that results from the position of the associated third layer trench 19. A structuring of the solar cells 2 by means of the first through third structuring lines 22-24 occurs along the first direction (x). Accordingly, the solar cell strings 28, 29 are, in each case, series connected along the second direction (y), which corresponds to the shorter dimension of the thin-film solar module 1 or substrate 4.

The two solar cell strings 28, 29 have an antiparallel forward direction, with the first solar cell string 28 conductive along the negative second direction (−y) and the second solar cell string 29 conductive along the positive second direction (y). The production of the antiparallel solar cell strings 28, 29 by means of the three structuring steps P1, P2, P3, is explained in greater detail below.

In the thin-film solar module 1, at least along the first direction (x) on both sides, a narrow edge region 30, 31, respectively, is formed, which serve, among other things, as contact zones for the solar cell strings 28, 29, with respective electrode layers exposed for this purpose. Thus, a first connecting contact 32 is formed in a first edge region 30 in the first module region 26 and a third connecting contact 34 is formed in the second module region 27; they are electrically separated from each other. In juxtaposition to this, an intermediate contact 33 is formed in a second edge region 31 over the two module regions 26, 27. The contacts 32-34 are configured here, for example, in the form of metal strips that can, in particular, be made of aluminum.

Here, the first connecting contact 32 is electrically conductively connected via the first solar cell string 28 to the intermediate contact 34, with—analogous to the electrical connection of the front electrode of a preceding solar cell 2 to the rear electrode of a following solar cell 2—the first connecting contact 32 being electrically connected to the front electrode of the first solar cell 2 and the intermediate contact 34 being electrically connected to the rear electrode of the last solar cell 2.

The electrical connection of the intermediate contact 34 to the rear electrode of the last solar cell 2 is discernible in FIG. 2, right image, which is a cross-sectional view of the thin-film solar module 1 in the second edge region 31. According to it, the rear electrode layer 7 extends into the second edge region 31, with the intermediate contact 34 mounted on the rear electrode layer 7.

In addition, the intermediate contact 34 is electrically conductively connected via the second solar cell string 29 to the second connecting contact 33, with—analogous to the connection in the first module region 26—the intermediate contact 34 being electrically conductively connected to the front electrode of the first solar cell 2 and the second connecting contact 33 being electrically conductively connected to the rear electrode of the last solar cell 2 of the second solar cell string 29.

The electrical contacts 32-34 in the two edge regions 31, 32 can, for example, be produced by welding, gluing, or soldering, preferably by ultrasonic welding. According to the invention, for the connection, respective exposed electrode layers are welded, glued, or soldered to the metal strips according to the invention and a durably stable electrical connection is produced.

Thus, in the thin-film solar module 1, the first connecting contact 32 is electrically conductively connected to the second connecting contact 33 via the two solar cell strings 28, 29, which are series connected via the intermediate contact 34. In the series-connected solar strings 28, 29, all solar cells 2 are rectified.

Further provided in the first edge region 30 is a connection box 35 common to the two solar cell strings 28, 29, which is disposed on the rear side of the substrate 4 opposite the main surface 6 and is provided with a device for the connection of the two connecting contacts 32, 33. For example, the two connecting contacts 32, 33 are connected to the connection box 35 by means of a detachable or fixed apparatus. The connection box 35 serves for the electrical connecting of the thin-film solar module 1 to an electrical load, for example, an inverter (not shown in the figures).

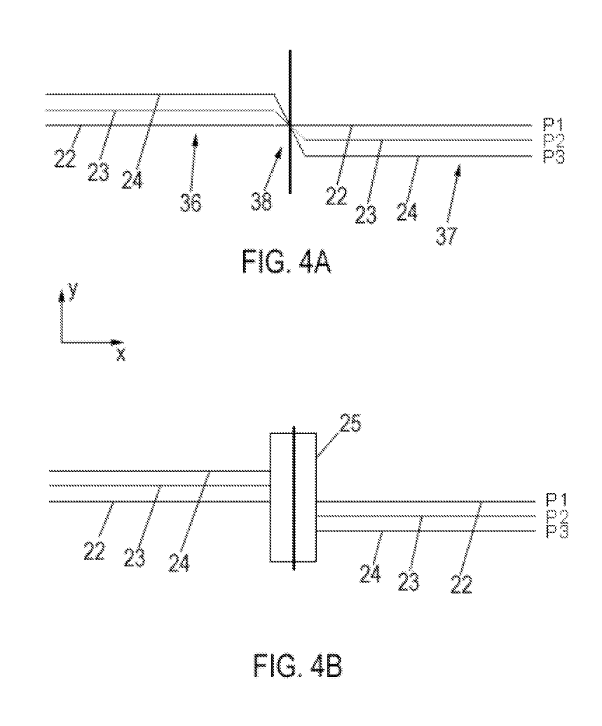

Referring to FIGS. 4A and 4B, a method for the structuring of the layer structure 5 during production of the thin-film solar module 1 is now explained.

According to the figures, the first structuring line 22 of the structuring step P1 is guided in a straight line over the complete layer structure 5 along the first direction (x). In contrast to this, the two remaining structuring lines 23, 24 of the structuring steps P2, P3 have, in the zones 36, 37 corresponding to the two module regions 26, 27, in each case, a lateral offset along the second direction (y). Thus, the second structuring line 23 in a first zone 36 of the layer structure 5 corresponding to the first module region 26 is disposed offset relative to the first structuring line 22 in a positive second direction (y); whereas in a second zone 37 of the layer structure 5 corresponding to the second module region 27, it is disposed offset relative to the first structuring line 22 in a negative second direction (−y). On the other hand, the third structuring line 24 in the first zone 36 is disposed offset relative to the second structuring line 23 in a positive second direction (y); whereas in the second zone 37 of the layer structure 5, it is disposed offset relative to the second structuring line 23 in a negative second direction (−y). Preferably, for this purpose, the second and third structuring line 23, 24, in each case, cross the first structuring line 22 in a third zone 38 provided for the formation of the region trench 25, while the third structuring line 24 disposed offset relative to the second structuring line 23 along the positive second direction (y) in the first zone 36 is disposed offset relative to the second structuring line 23 along the negative second direction (−y) in the second zone 37. As a result of this, the spatial sequence of the three structuring lines 22-24 in the first zone 36 is reversed relative to a spatial sequence of the three structuring lines 22-24 in the second zone 37 of the layer structure 5, with, in the first zone 36, the first, second, and third structuring line disposed one after another along the positive second direction (y), whereas, in the second zone 37, the third, second, and first structuring line are disposed one after another along the positive second direction (y).

In a further step, the region trench 25 in the third zone 38 is configured by removing the layer structure 5 all the way to the substrate 4 for this purpose. By the formation of the region trench 25, the two module regions 26, 27 electrically separated from each other are formed. The region trench 25 is formed only in the third zone 38 of the layer structure 5, in which sections of the structuring lines 23, 24 running at an angle relative to the first direction (x) are present. As already mentioned, a reversal of the sequence of the structuring lines can be simply obtained by means of the lateral offsetting of the second and third structuring lines 23, 24 along the second direction (y), resulting in the fact that the forward directions of the solar cells 2 in the two module regions 25, 26 are reversed or antiparallel.

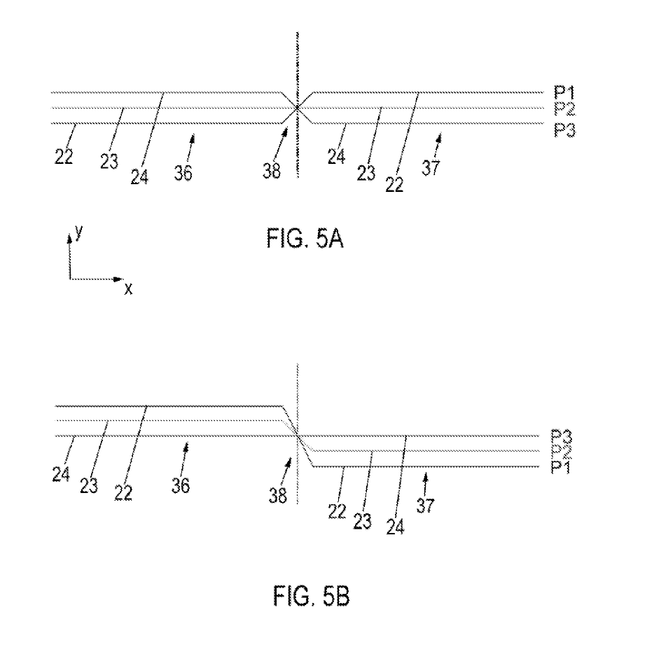

In a variant of the method for structuring the layer structure 5 illustrated in FIG. 5A, instead of the first structuring line 22, the second structuring line 23 of the structuring step P2 is guided in a straight line over the complete layer structure 5 along the first direction (x). In contrast to this, the two remaining structuring lines 22, 24 in the first and second zones 36, 37 have, in each case, a lateral offset along the second direction (y). Here, the first structuring line 22 in the first zone 36 of the layer structure 5 is disposed offset relative to the second structuring line 23 along the negative second direction (−y); whereas, in the second zone 37 of the layer structure 5, it is disposed offset relative to the second structuring line 23 in a positive second direction (y). On the other hand, the third structuring line 24 in the first zone 36 is disposed offset relative to the second structuring line 23 in a positive second direction (y); whereas, in the second zone 37 of the layer structure 5, it is disposed offset relative to the second structuring line 23 in a negative second direction (−y). Preferably, for this purpose, the first and third structuring line 22, 24, in each case, cross the second structuring line 22 in the third zone 38. Thus, the spatial sequence of the three structuring lines 22-24 in the first zone 36 is reversed relative to a spatial sequence of the three structuring lines 22-24 in the second zone 37 of the layer structure 5, with, in the first zone 36, the first, second, and third structuring line disposed one after another along the positive second direction (y), whereas, in the second zone 37, the third, second, and first structuring line are disposed one after another along the positive second direction (y).

In a further variant of the method for structuring the layer structure 5 illustrated in FIG. 5B, the third structuring line 24 is guided in a straight line over the complete layer structure 5 along the first direction (x). In contrast to this, the two remaining structuring lines 22, 23 in the two zones 36, 37 have, in each case, a lateral offset along the second direction (y). Here, the second structuring line 23 in the first zone 36 is disposed offset relative to the third structuring line 24 along the positive direction (y); whereas, in the second zone 37, it is disposed offset relative to the third structuring line 24 in a negative second direction (−y). On the other hand, the first structuring line 22 in the first zone 36 is disposed offset relative to the second structuring line 23 in a positive second direction (y); whereas, in the second zone 37, it is disposed offset relative to the second structuring line 23 in a negative second direction (−y). Preferably, for this purpose, the first and second structuring line 22, 23, in each case, cross the third structuring line 24 in the third zone 38. Thus, the spatial sequence of the three structuring lines 22-24 in the first zone 36 is reversed relative to a spatial sequence of the three structuring lines 22-24 in the second zone 37 of the layer structure 5, with, in the first zone 36, the first, second, and third structuring line disposed one after another along the positive second direction (y), whereas, in the second zone 37, the third, second, and first structuring line are disposed one after another along the positive second direction (y).

The different variants of the method for structuring the layer structure 5 can be part of a method for producing the thin-film solar module 1.

In a first variant of an exemplary method for producing the thin-film solar module 1, the first variant for structuring the layer structure 5, illustrated in FIGS. 4A and 4B, is used. In it, the following steps are successively performed:
Coating the substrate 4 with the rear electrode layer 7 (molybdenum);
Structuring step P1 for producing insulated rear electrode sections 14, 15 of the rear electrode layer 7, wherein the first structuring line 22 has a linear progression;
Deposition or formation of the doped absorber layer 8 (Cu—Ga—In—(Se/S):Na);
Deposition of a first layer of the buffer layer 9 (CdS); Deposition of a second layer of the buffer layer 9 (i-ZnO);
Structuring step P2 for producing an electrical connection between the front electrode section and rear electrode section of adjacent solar cells, wherein the second structuring line 23 is laterally offset according to FIG. 4A;
Deposition of the doped front electrode layer 10 (ZnO:A)
Structuring step P3 for structuring the adjacent solar cells 2, wherein the third structuring line 24 is laterally offset according to FIG. 4A and decoating of the layer structure 5 all the way to the rear side for formation of contact zones inside the two edge regions 30, 31;
Decoating the two edge regions 30, 31 except for the contact zones and, optionally, additional, not further identified, edge regions along the substrate 4 and decoating the region trench 25 all the way to the substrate 4;
Producing the intermediate contacts and connecting contacts 32-34 (Al-metal strips);
Laminating the layer structure 5 with the plastic layer 11;
Installing the connection box 35, as well as connection of the connection box 35 to the two connecting contacts 32,33.

In a second variant of an exemplary method for producing the thin-film solar modules 1, the second variant of the method for structuring the layer structure 5, illustrated in FIG. 5A, is used. In it, the following steps are successively performed:
Coating the substrate 4 with the rear electrode layer 7 (molybdenum);
Structuring step P1 for producing insulated rear electrode sections 14, 15 of the rear electrode layer 7, wherein the first structuring line 22 according to FIG. 5A is laterally offset;
Deposition or formation of the doped absorber layer 8 (Cu—Ga—In—(Se/S):Na);
Deposition of a first layer of the buffer layer 9 (CdS);
Deposition of a second layer of the buffer layer 9 (i-ZnO);
Structuring step P2 for producing an electrical connection between the front electrode section and rear electrode section of adjacent solar cells, wherein the second structuring line 23 has a linear progression;
Deposition of the doped front electrode layer 10 (ZnO:A)
Structuring step P3 for structuring the adjacent solar cells 2, wherein the third structuring line 24 is laterally offset according to FIG. 5A;
Decoating the two edge regions 30, 31 and, optionally, additional, not further identified, edge regions along the shorter dimension of the substrate 4 and decoating the region trench 25;
Producing the intermediate contacts and connecting contacts 32-34 (Al-metal strips);
Laminating the layer structure 5 with the plastic layer 11;
Installing the connection box 35, as well as connection of the connection box 35 to the two connecting contacts 32,33.

In a third variant of an exemplary method for producing the thin-film solar module 1, the third variant of the method for structuring the layer structure 5, illustrated in FIG. 5B, is used. In it, the following steps are successively performed:
Coating the substrate 4 with the rear electrode layer 7 (molybdenum);
Structuring step P1 for producing insulated rear electrode sections 14, 15 of the rear electrode layer 7, wherein the first structuring line 22 is laterally offset according to FIG. 5B;
Deposition or formation of the doped absorber layer 8 (Cu—Ga—In—(Se/S):Na);
Deposition of a first layer of the buffer layer 9 (CdS);
Deposition of a second layer of the buffer layer 9 (i-ZnO);
Structuring step P2 for producing an electrical connection between the front electrode section and rear electrode section of adjacent solar cells, wherein the second structuring line 23 is laterally offset according to FIG. 5B;
Deposition of the doped front electrode layer 10 (ZnO:A)
Structuring step P3 for structuring the adjacent solar cells 2, wherein the third structuring line 24 has a linear progression and decoating of the layer structure 5 all way to the rear side for formation of contact zones inside the two edge regions 30, 31;
Decoating the two edge regions 30, 31 except for the contact zones and, optionally, additional, not further identified, edge regions along the substrate 4 and decoating the region trench 25 all way to the substrate 4;
Producing the intermediate contacts and connecting contacts 32-34 (Al-metal strips);
Laminating the layer structure 5 with the plastic layer 11;
Installing the connection box 35, connection of the connection box 35 to the two connecting contacts 32, 33.

The different variants for producing the thin-film solar module 1 enable a simple creation of the antiparallel solar cell strings 28 29 by means of a suitable guidance of the structuring lines 22-24 during the structuring of the layer structure 5. Advantageously, the region trench 25 is decoated together with, preferably simultaneously with, the two edge regions 30, 31 outside the contact zones all the way to the substrate.

A particular advantage of the thin-film solar module 1 consists in that only a single connection box 35 is necessary for the connection of the two connecting contacts 32, 33, as a result of which the production costs can be reduced and the long-term stability and reliability of the thin-film solar module 1 are improved because of a corrosive susceptibility to failure of the connection boxes 35 in particular due to penetration of moisture. By means of the antiparallel solar cell strings 28, 29, the two connecting contacts 32, 33 are disposed on the same side of the thin-film solar module 1, such that it is advantageously possible to forgo expensive wiring for the electrical connection of the two connecting contacts 32, 33 to the common connection box 35, which, in the substrate configuration, would, moreover, lead to undesired shadowing of photovoltaically active regions. Through the series connection of the two connecting contacts 32, 33 by means of the two solar cell strings 28, 29, which, in turn, are series connected to each other by means of the intermediate contact 34, a U-shaped configuration is created.

The width of the region trench 25 depends, among other things, on the breakdown voltage of the two module regions 26, 27 and falls, for example, in a range from 1 to 10 mm The region trench 25 can be filled with an electrically insulating material in order to boost the breakdown resistance. From the standpoint of production technology, the width of the region trench 25 can depend on the writing speed of the structuring lines 22-24. The division of the thin-film solar module 1 into two roughly equal-sized module regions 26, 27 results in a halving of the solar cell current and a doubling of the solar cell voltage. Thus, the solar cell current is a function of the width of the solar cell 2 measured along the first direction (x), which falls, for example, in the range from 1 to 11 mm, preferably in the range from 2 to 8 mm, and is, in particular, approx. 5.5 mm, in order to obtain a favorable current/voltage characteristic for the technical application.

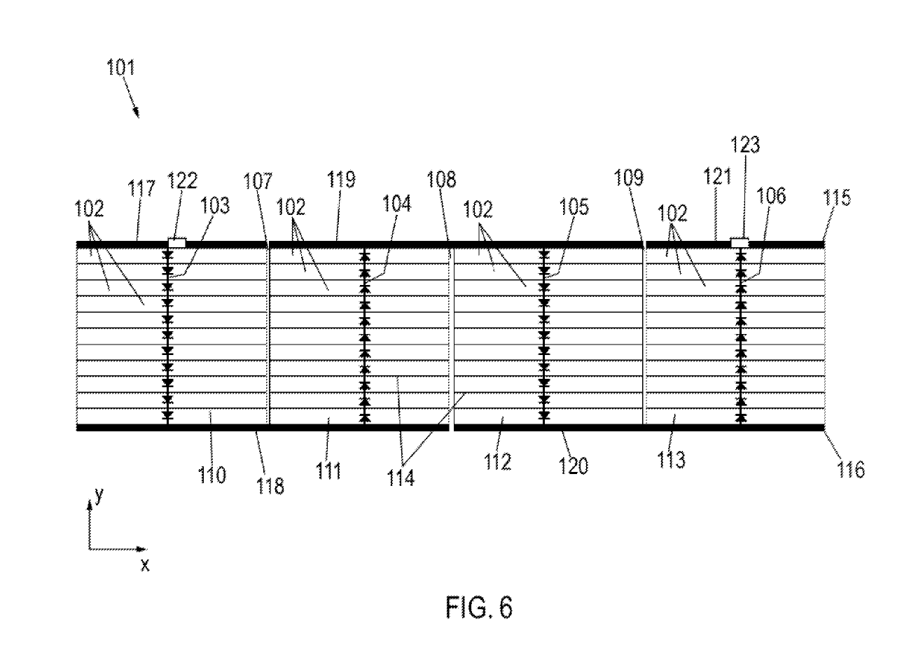

Referring to FIG. 6, a second embodiment of a thin-film solar module 1 according to the invention identified as a whole by the reference number 101 is now described, describing only the differences relative to the first exemplary embodiment to avoid unnecessary repetition and, for the rest, referring to the statements made there.

According to the figures, the module area of the thin-film solar module 101 is divided into a plurality of individual solar cells 102 that are connected to each other in a first solar cell string 103, a second solar cell string 104, a third solar cell string 105, and a fourth solar cell string 106, in series connection in each case. The thin-film solar module 101, which has, in the top view, a rectangular shape, is divided into a first module region 110, a second module region 111, a third module region 112, and a fourth module region 113, with the first module region 110 and the second module region 111 electrically separated from each other by a first region trench 107; the second module region 111 and the third module region 112, by a second region trench 108; and the third module region 112 and the fourth module region 113, by a third region trench 109. The module regions 110-113 have the same shape and size and are arranged next to each other in a row in a first direction (x) defined by the longer dimension of the thin-film solar module 101. The region trenches 107-109 run, in each case, in a straight line along the second direction (y) perpendicular thereto.

Each module region 110-113 has a separate solar cell string, with the first solar cell string 103 formed in the first module region 110, the second solar cell string 104 in the second module region 111, the third solar cell string 105 in the third module region 112, and the fourth solar cell string 106 in the fourth module region 113. In each solar cell string 103-106, the solar cells 102 are, in each case, rectified and series connected. The strip-shaped solar cells 102 extend along the first direction (x) and are disposed along the second direction (y), with adjacent solar cells 103 separated from each other by a (theoretical) separating line 114 running along the first direction (x). Structuring of the solar cells 102 by means of the first through the third structuring steps P1-P3 takes place along the first direction (x). Accordingly, the solar cell strings 103-106 are series connected, in each case, along the second direction (y), which corresponds to the shorter dimension of the thin-film solar module 101. In the thin-film solar module 101, adjacent solar cell strings 103-106 have, in each case, an antiparallel forward direction, with the first solar cell string 103 conductive in the negative second direction (−y), the second solar cell string 29 conductive along the positive second direction (y), the third solar cell string 105 conductive along the negative second direction (−y), and the fourth solar cell string 106 conductive along the positive second direction (y).

In the thin-film solar module 101, along the first direction (x) on both sides, a narrow edge region 115, 116, respectively, is formed, which serve, among other things, as contact zones for the solar cell strings 103-106, with respective electrode layers exposed for this purpose. Thus, a first connecting contact 117 is formed in a first edge region 115 in the first module region 110, a second intermediate contact 119 is formed over the second and third module region 111, 112, and a second connecting contact 121 is formed in the fourth module region 113; they are, in each case, electrically separated from each other. In juxtaposition to this, a first intermediate contact 118 is formed in a second edge region 116 over the first and second module region 110, 111, and a third intermediate contact 120 is formed over the third and fourth module region 112, 113; they are electrically separated from each other. The contacts 117-121 are configured here, for example, in the form of metal strips that can, in particular, be made of aluminum. Here, the first connecting contact 117 is electrically conductively connected via the first solar cell string 103 to the first intermediate contact 118, the first intermediate contact 118 is electrically conductively connected via the second solar cell string 104 to the second intermediate contact 119, the second intermediate contact 119 is electrically conductively connected via the third solar cell string 105 to the third intermediate contact 120, and the third intermediate contact 120 is electrically conductively connected via the fourth solar cell string 106 to the second connecting contact 121.

Thus, in the thin-film solar module 101, the first connecting contact 117 is electrically conductively connected via the four series-connected solar cell strings 103-106 to the second connecting contact 121. In the series-connected solar cell strings 103-106, all solar cells 102 are rectified.

Further provided in the first edge region 115 in the first module region 110 is a connection box 122 connected to the first connecting contact 117, which box is disposed on the rear side of the thin-film solar module 101 and is provided with a device for the connection of the first connecting contact 117. In addition, provided in the first edge region 115 in the fourth module region 113 is a second connection box 123 connected to the second connecting contact 121, which is likewise disposed on the rear side of the thin-film solar module 101 and is provided with a device for the connection of the second connecting contact 121. The two connection boxes 122, 123 serve for the electrical connecting of the thin-film solar module 101 to an electrical load, for example, an inverter.

Alternatively, even in this configuration, the connecting contacts 117 and 121 can also be connected in a connection box 122, 123.

The production of the antiparallel solar cell strings 103-106 can occur according to a lateral offset of the structuring lines explained with reference to FIGS. 4A, 4B, 5A, and 5B in the three structuring steps P1-P3, with a reversal of a solar cell string direction along the negative second direction (−y) into a solar cell string direction along the positive second direction (y) by means of the linear progression of a structuring line and the lateral offset of the two other structuring lines depicted in the figures, while a reversal of a solar cell string direction along the positive second direction (y) into a solar cell string direction along the negative second direction (−y) is obtained by means of a mirror image lateral offset of the two other structuring lines relative to the linear structuring line. The thin-film solar module 101 depicted in FIG. 6 can be produced by the above-presented variants of the production method, wherein such a structuring method is used by which a simple creation of the antiparallel solar cell strings 103-106 is made possible. Advantageously, the region trenches 107-109 are decoated together with, preferably simultaneously with, the edge regions 115, 116.

A particular advantage of the thin-film solar module 101 consists in that, per pair of antiparallel solar cell strings 103-106, only a single connection box 122, 123 is necessary for the connection of a connecting contact 117, 121, as a result of which the production costs can be reduced and the long-term stability and reliability of the thin-film solar module 101 are improved. By means of the series connection of the two connecting contacts 117, 121 via the four solar cell strings 103-106, which are, for their part, serially connected to each other via the intermediate contacts 118-120, a configuration consisting of a plurality of connected U's is created that makes it possible to forgo expensive wiring. Through the adjustment of the number and size of the module regions 110-113, in particular the number of the series-connected U's, it is possible to selectively influence the current/voltage characteristic of the thin-film solar module 101. Although a thin-film solar module 101 with four module regions 110-113 is depicted in FIG. 6, it is understood that a greater or smaller number of module regions can be provided. It is preferred to have an even number of module regions, with adjacent solar cell strings having an antiparallel forward direction.

The invention makes available a thin-film solar module that can be produced cost-effectively in industrial series production and whose long-term stability and durability is improved compared to conventional thin-film solar modules. The current/voltage characteristic of the thin-film solar module can be selectively influenced as desired.

### LIST OF REFERENCE CHARACTERS

1 Thin-film solar module
2 Solar cell
3 Separating line
4 Substrate
5 Layer structure
6 Main surface
7 Rear electrode layer
8 Absorber layer
9 Buffer layer
10 Front electrode layer
11 Plastic layer
12 Cover plate
13 First layer trench
14 First rear electrode section
15 Second rear electrode section
16 Second layer trench
17 First semiconductor section
18 Second semiconductor section
19 Third layer trench
20 First front electrode section
21 Second front electrode section
22 First structuring line
23 Second structuring line
24 Third structuring line
25 Region trench
26 First module region
27 Second module region
28 First solar cell string
29 Second solar cell string
30 First edge region
31 Second edge region
32 First connecting contact
33 Second connecting contact
34 Intermediate contact
35 Connection box
36 First zone
37 Second zone
38 Third zone
101 Thin-film solar module
102 Solar cell
103 First solar cell string
104 Second solar cell string
105 Third solar cell string
106 Fourth solar cell string
107 First region trench
108 Second region trench
109 Third region trench
110 First module region
111 Second module region
112 Third module region
113 Fourth module region
114 Separating line
115 First edge region
116 Second edge region
117 First connecting contact
118 First intermediate contact
119 Second intermediate contact
120 Third intermediate contact
121 Second connecting contact
122 First connection box
123 Second connection box

1. A solar cell array, in particular for thin-film solar modules, comprising a substrate, onto which a layer structure having a plurality of layers is applied, wherein the layer structure is divided into a plurality of different regions that are electrically separated from each other by one or a plurality of region trenches, wherein a solar cell string that includes a plurality of series-connected, rectified solar cells is formed in each region.

2. The solar cell array according to claim 1, wherein the solar cell strings are series connected by one or a plurality of intermediate contacts.

3. The solar cell array according to claim 1, wherein the layer structure has a first electrode layer, a second electrode layer, and a semiconductor layer disposed between the two electrode layers, by means of which a pn-junction is formed, wherein the semiconductor layer is formed from a chalcopyrite compound, cadmium telluride, and/or silicon.

4. The solar cell array according to claim 1, with a first connecting contact and a second connecting contact that are electrically connected to each other by the solar cell strings, wherein the solar cell strings are series-connected by one or a plurality of intermediate contacts, at least one connection housing, in which the two connecting contacts are connected.

5. The solar cell array according to claim 4, wherein:
the layer structure is divided into two regions that are electrically separated from each other by a region trench,
the first connecting contact and the second connecting contact are electrically connected to each other by the two solar cell strings, wherein the two solar cell strings are series connected by an intermediate contact,
the two connecting contacts are connected to a common connection housing.

6. The solar cell array according to claim 4, wherein:
the layer structure is divided into four regions that are electrically separated from each other by three region trenches,
the first connecting contact and the second connecting contact are electrically connected to each other by the four solar cell strings, with the four solar cell strings series connected by three intermediate contacts,
the two connecting contacts are in each case connected to a separate connection housing.

7. The solar cell array according to claim 1, wherein the solar cells are in each case configured as a strip.

8. The solar cell array according to claim 1, wherein the connection contacts and intermediate contacts are in each case configured in the form of a contact strip.

9. The solar cell array according to claim 1, wherein the at least one region trench has a width measured transverse to its length in the range from 0.5 to 10 mm.

10. The solar cell array according to claim 1, wherein the at least one region trench is filled in with an electrically insulating material.

11. A thin-film solar module, which is configured in the form of the solar cell array according to claim 1.

12. The thin-film solar module according to claim 11, wherein the first electrode layer is a transparent front electrode layer and the second electrode layer is a rear electrode layer, with the substrate disposed on a side of the rear electrode layer facing away from the front electrode layer.

13. A method for the structuring of a layer structure of a thin-film solar module, comprising a first electrode layer, a second electrode layer, and a semiconductor layer disposed between the two electrode layers, the method comprising the following steps:
forming a first structuring line in the second electrode layer, by means of which the second electrode layer is divided into second layer sections electrically separated from each other,
forming a second structuring line for the electrical connection of the first electrode layer and the second electrode layer for series connection of the solar cells,
forming a third structuring line in the first electrode layer, by means of which the first electrode layer is divided into first layer sections electrically separated from each other,
wherein one structuring line, selected from among the first through the third structuring lines is guided such that it has a linear progression over at least two regions electrically separated from each other, while the two remaining structuring lines and the one structuring line are offset relative to each other such that a sequence of the structuring lines is reversed.

14. The method according to claim 13, wherein a structuring line, selected from among the first through the third structuring lines is guided such that it has a linear progression over at least two regions electrically separated from each other, while the two remaining structuring lines intersect said selected structuring line such that a sequence of the structuring lines is reversed.

15. A method for the production of a thin-film solar module, comprising the following steps:
applying a layer structure on a substrate, wherein the layer structure has at least a first electrode layer, a second electrode layer, and a semiconductor layer disposed between the two electrode layers, by means of which semiconductor layer a pn-junction is formed,
structuring of the layer structure by the method according to claim 14, such that a plurality of solar cell strings is created, each of which consists of a plurality of series-connected, rectified solar cells, wherein solar cell strings adjacent each other can have, in particular, an antiparallel forward direction,
introducing of one or a plurality of region trenches in the layer structure, such that different module regions, each of which contains a separate solar cell string, are electrically separated from each other,
series connecting the solar cell strings by forming one or a plurality of intermediate contacts,
forming of a first connecting contact and a second connecting contact that are electrically conductively connected to the solar cell strings,
connecting of the two connecting contacts in at least one connection housing.
